(19) United States
(12) Patent Application Publication
(10) Pub. No.: US 2013/0248954 A1
(43) Pub. Date: Sep. 26, 2013

(54) Unit Pixel of Image Sensor and Image Sensor Including the Same

(71) Applicant: SAMSUNG ELECTRONICS CO., LTD., Suwon-si (KR)

(72) Inventor: Jung-Chak Ahn, Yongin-si (KR)

(73) Assignee: Samsung Electronics Co., Ltd., Suwon-si (KR)

(21) Appl. No.: 13/764,916

(22) Filed: Feb. 12, 2013

(30) Foreign Application Priority Data
Mar. 21, 2012 (KR) 10-2012-0028694

(51) Int. Cl. H01L 31/0232; H01L 31/02

(52) U.S. Cl. CPC H01L 31/0232; H01L 31/02
USPC 257/292; 257/290

(57) ABSTRACT

Unit pixels included in an image sensor are provided. The unit pixel including a photoelectric conversion region in a semiconductor substrate, the photoelectric conversion region configured to generate photo-charges corresponding to incident light; a transfer gate on a first surface of the semiconductor substrate, the transfer gate configured to transmit the photo-charges from the photoelectric conversion region to a floating diffusion region in the semiconductor substrate; and a suppression gate on the first surface of the semiconductor substrate, the suppression gate configured to correspond to the photoelectric conversion region, the suppression gate including polysilicon and a negative voltage applied to the suppression gate to reduce dark currents is generated adjacent to the first surface of the semiconductor substrate.

### CROSS-REFERENCE TO RELATED APPLICATIONS

This application claims priority under 35 USC §119 to Korean Patent Application No. 10-2012-0028694, filed on Mar. 21, 2012 in the Korean Intellectual Property Office (KIPO), the contents of which are herein incorporated by reference in their entirety.

### FIELD

The inventive concept relates generally to image sensors and, more particularly, to unit pixels of image sensors and back-illuminated image sensors including the unit pixels.

### BACKGROUND

An image sensor is a device that transforms incident light to an electric signal. A charge coupled device (CCD) image sensor and a complementary metal oxide semiconductor (CMOS) image sensor may be used. To improve sensing performance, a backside illuminated image sensor (BIS) that performs photoelectric transformation in response to an incident light passing through a back surface of a semiconductor substrate has been used.

### SUMMARY

Some embodiments of the present inventive concept provide unit pixels included in an image sensor, the unit pixel including a photoelectric conversion region in a semiconductor substrate, the photoelectric conversion region configured to generate photo-charges corresponding to incident light; a transfer gate on a first surface of the semiconductor substrate, the transfer gate configured to transmit the photo-charges from the photoelectric conversion region to a floating diffusion region in the semiconductor substrate; and a suppression gate on the first surface of the semiconductor substrate, the suppression gate configured to correspond to the photoelectric conversion region, the suppression gate including polysilicon and a negative voltage applied to the suppression gate to reduce dark currents is generated adjacent to the first surface of the semiconductor substrate.

In further embodiments, the semiconductor substrate may have a first conductivity type and the photoelectric conversion region may have doped impurities having a second conductivity type, opposite first conductivity type.

In still further embodiments, a first impurity region may be provided in the semiconductor substrate above the photoelectric conversion region. The first impurity region may be doped with impurities having the first conductivity type and may have a higher doping concentration than the semiconductor substrate.

In some embodiments, a first impurity region may be provided in the semiconductor substrate under the photoelectric conversion region. The first impurity region may be doped with impurities having the second conductivity type and may have a lower doping concentration than the photoelectric conversion region.

In further embodiments, a thickness of the suppression gate may be substantially the same as a thickness of the transfer gate.

In still further embodiments, a color filter may be provided on a second surface of the semiconductor substrate. The color filter may be configured to correspond to the photoelectric conversion region. A micro lens may be provided on the color filter. The micro lens may be configured to correspond to the photoelectric conversion region.

In some embodiments, the incident light may pass through the micro lens, the color filter and the second surface of the semiconductor substrate, and reach the photoelectric conversion region.

In further embodiments, a protection layer may be provided between the second surface of the semiconductor substrate and the color filter. The protection layer may be doped with impurities having the second conductivity type and may have a higher doping concentration than the semiconductor substrate.

In still further embodiments, a dielectric layer may be provided between the second surface of the semiconductor substrate and the color filter.

In some embodiments, the dielectric layer may include negative fixed charges.

In further embodiments, the color filter may include one of a red filter, a green filter and a blue filter.

In still further embodiments, the color filter may include one of a yellow filter, a magenta filter and a cyan filter.

In some embodiments, an isolation region may be provided surrounding the unit pixel.

Further embodiments of the present inventive concept provide image sensors including a pixel array including a plurality of unit pixels, the pixel array configured to generate electric signals based on incident light; and a signal processing unit configured to generate image data based on the electric signals. Each unit pixel includes a photoelectric conversion region in a semiconductor substrate, the photoelectric conversion region configured to generate photo-charges corresponding to the incident light; a transfer gate on a first surface of the semiconductor substrate, the transfer gate configured to transmit the photo-charges from the photoelectric conversion region to a floating diffusion region in the semiconductor substrate; and a suppression gate on the first surface of the semiconductor substrate, the suppression gate configured to correspond to the photoelectric conversion region and including polysilicon and a negative voltage applied to the suppression gate to reduce dark currents is generated adjacent to the first surface of the semiconductor substrate.

In still further embodiments, a negative voltage generator may be configured to generate the negative voltage applied to the suppression gate.

### BRIEF DESCRIPTION OF THE DRAWINGS

Illustrative, non-limiting example embodiments will be more clearly understood from the following detailed description taken in conjunction with the accompanying drawings.

FIG. 1 is a cross-section illustrating a unit pixel of an image sensor according to some embodiments of the present inventive concept.

FIGS. 2A-2H are cross-sections of a unit pixel illustrating processing steps in the fabrication of unit pixels illustrated in FIG. 1.

FIGS. 3-6 are cross-sections of a unit pixel of an image sensor according to some embodiments of the present inventive concept.

FIG. 7 is a block diagram illustrating an image sensor including the unit pixel according to some embodiments of the present inventive concept.

FIG. 8 is a circuit diagram illustrating an example of a unit pixel included in the image sensor of FIG. 7.

FIG. 9 is a diagram illustrating a system according to some embodiments of the present inventive concept.

FIG. 10 is a block diagram illustrating an example of an interface used in the computing system of FIG. 9.

### DETAILED DESCRIPTION OF THE EMBODIMENTS

Various example embodiments of the present inventive concept will be described more fully with reference to the accompanying drawings, in which embodiments are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the inventive concept. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

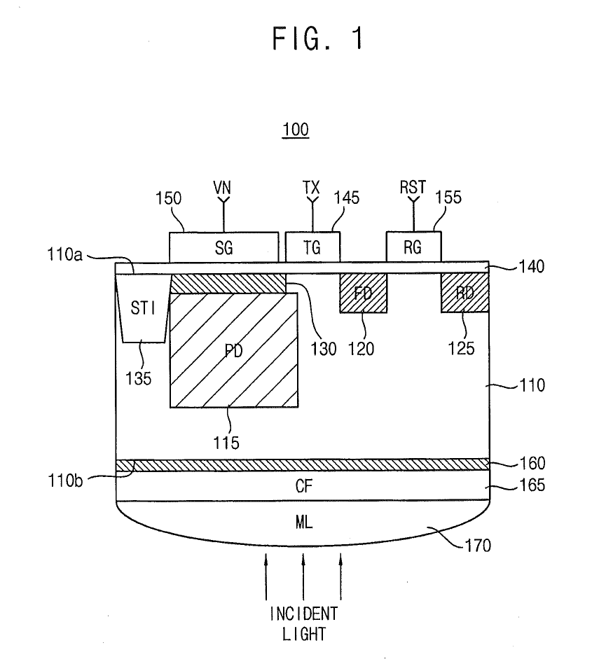

Referring first to FIG. 1, a cross-section illustrating a unit pixel of an image sensor according to some embodiments will be discussed. As illustrated in FIG. 1, a unit pixel 100 of an image sensor includes a photoelectric conversion region (PD) 115 in a semiconductor substrate 110, and a transfer gate (TG) 145 and a suppression gate (SG) 150 on the semiconductor substrate 110. The unit pixel 100 of the image sensor may further include a floating diffusion region (FD) 120, a reset drain region (RD) 125, a first impurity region 130, an isolation region (STI) 135, a first dielectric layer 140, a reset gate (RG) 155, a protection layer 160, a color filter (CF) 165 and a micro lens (ML) 170.

The image sensor including the unit pixel 100 may be one of various image sensors, such as a complementary metal-oxide semiconductor (CMOS) image sensor and/or a charge-coupled device (CCD) image sensor. The image sensor including the unit pixel 100 according to some embodiments will be discussed herein based on a CMOS image sensor. However, it will be understood that embodiments are not limited to this configuration.

The semiconductor substrate 110 has a front surface 110a and a back surface 110b. The unit pixel 100 may be included in a backside illuminated image sensor (BIS) that generates image data in response to incident lights passing through the back surface 110b of the semiconductor substrate 110. The semiconductor substrate 110 may include an epitaxial layer and may be doped with, for example, p-type impurities.

In the image sensor including the unit pixel 100 according to some embodiments, a plurality of gate structures 145, 150, 155, which transfer and amplify electric signals corresponding to the incident lights, may be disposed on the front surface 110a of the semiconductor substrate 110. The color filter 165 and the micro lens 170, through which the incident lights passes, may be disposed on the back surface 110b of the semiconductor substrate 110. In the BIS, because the gate structures and metal lines connected to the gate structures are not disposed between the micro lens 170 and the photoelectric conversion region 115, diffused reflection and/or scattering due to the gate structures 145, 150, 155 and the metal lines may not occur, and the distance from the micro lens 170 to the photoelectric conversion region 115 may be shorter. Accordingly, light guiding efficiency and light sensitivity may be improved in the BIS.

The photoelectric conversion region 115 is in the semiconductor substrate 110. The photoelectric conversion region 115 is configured to generate photo-charges corresponding to the incident lights. For example, the photoelectric conversion region 115 may generate electron-hole pairs in response to the incident lights, and may collect the electrons and/or the holes of the electron-hole pairs. The photoelectric conversion region 115 may be doped with first-type impurities, for example, n-type impurities, of an opposite conductivity type to that of the semiconductor substrate 110. The photoelectric conversion region 115 may include a photo diode, a photo transistor, a photo gate, a pinned photo diode (PPD) and/or a combination thereof.

The transfer gate 145 is formed on a first surface, for example, the front surface 110a, of the semiconductor substrate 110. The transfer gate 145 is configured to transmit the photo-charges from the photoelectric conversion region 115 to the floating diffusion region 120 formed in the semiconductor substrate 110. The transfer gate 145 may receive a transfer signal TX. When the transfer signal TX is activated, the photo-charges may be transmitted from the photoelectric conversion region 115 to the floating diffusion region 120.

The suppression gate 150 is formed on the first surface 110a of the semiconductor substrate 110. The suppression gate 150 is configured to correspond to the photoelectric conversion region 115 and is formed of polysilicon. The suppression gate 150 and the transfer gate 145 are simultaneously formed. A negative voltage VN is applied to the suppression gate 150 to reduce the likelihood, or possibly prevent, dark currents generated adjacent to the first surface 110a of the semiconductor substrate 110. When the negative voltage VN is applied to the suppression gate 150, holes may be accumulated in a region adjacent to the first surface 110a of the semiconductor substrate 110. Electric charges generated without any incident light may be coupled with the holes accumulated in the region adjacent to the first surface 110a of the semiconductor substrate 110. Thus, dark currents of the image sensor including the unit pixel 100 may be reduced.

The floating diffusion region 120 may receive the photo-charges from the photoelectric conversion region 115 via the transfer gate 145. Image data may be generated based on a charge amount of the received photo-charges.

The reset gate 155 may be on the first surface 110a of the semiconductor substrate 110 and may receive a reset signal RST. The reset drain region 125 may be in the semiconductor substrate 110 and may receive a voltage, for example, a power supply voltage, for resetting the floating diffusion region 120. For example, when the reset signal RST is activated, the floating diffusion region 120 may be reset by discharging the charges accumulated in the floating diffusion region 120 based on the power supply voltage.

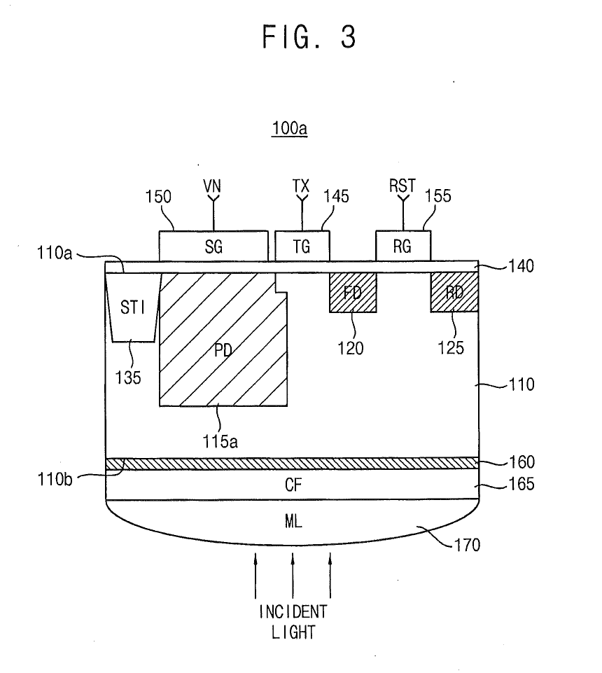

The first impurity region 130 may be in the semiconductor substrate 110 above the photoelectric conversion region 115. The first impurity region 130 may be doped with second-type impurities, for example, p-type impurities, of a same conductivity type to that of the semiconductor substrate 110, and may be doped with higher doping density than the semiconductor substrate 110. The first impurity region 130 may be provided to reduce the likelihood, or possibly prevent, the dark currents generated adjacent to the first surface 110a of the semiconductor substrate 110. For example, the first impurity region 130 may be doped with the p-type impurities with relatively high doping density. The electric charges generated without any incident light may be coupled with the holes in the first impurity region 130. Thus, the dark currents of the image sensor including the unit pixel 100 may be reduced. In some embodiments, the first impurity region 130 may be omitted as will be discussed further herein with reference to FIG. 3.

The isolation region 135 may be filled with dielectric material and may be formed to surround the unit pixel 100. The unit pixel 100 may be separated from neighboring unit pixels by the isolation region 135. The gate structures 145, 150, 155 may be electrically insulated from the semiconductor substrate 110 by the first dielectric layer 140. The first dielectric layer 140 may be referred to as a gate dielectric layer.

The protection layer 160 may be formed on a second surface, for example, the back surface 110b, of the semiconductor substrate 110. The second surface 110b may correspond to the first surface 110a. The protection layer 160 may be doped with the second-type impurities with higher doping density than the semiconductor substrate 110. Similarly to the first impurity region 130, the protection layer 160 may be provided to reduce the likelihood or, possibly prevent, dark currents generated adjacent to the second surface 110b of the semiconductor substrate 110. For example, the protection layer 160 may be doped with the p-type impurities with relatively high doping density. Electric charges generated without any incident light may be coupled with the holes in the protection layer 160. Thus, the dark currents of the image sensor including the unit pixel 100 may be reduced.

The color filter 165 may be formed on the second surface 110b, for example, on the protection layer 160. The color filter 165 may be disposed corresponding to the photoelectric conversion region 115. The color filter 165 may be included in a color filter array that includes a plurality of color filters disposed in the matrix pattern. In some embodiments, the color filter array may include a Bayer filter including red filters, green filters and/or blue filters. Thus, the color filter 165 may be one of the red, green and blue filters. In some embodiments, the color filter array may include yellow filters, magenta filters, and/or cyan filters, i.e., the color filter 165 may be one of the yellow, magenta and cyan filters. The color filter array may further include white filters without departing from the scope of the present inventive concept.

The micro lens 170 may be formed on the color filter 165. The micro lens 170 may be disposed corresponding to the photoelectric conversion region 115 and to the color filter 165, respectively. The micro lens 170 may adjust a path of light entering the micro lens such that the light is focused on a corresponding photoelectric conversion region. The micro lens 170 may be included in a micro lens array that includes a plurality of micro lenses disposed in the matrix pattern.

In some embodiments, an anti-reflection layer may be provided between the protection layer 160 and the color filter 165. The anti-reflection layer may reduce, or possibly prevent, the incident lights from being reflected by the back surface 110b of the semiconductor substrate 110. In some embodiments, the anti-reflective layer may be formed by alternately laminating materials having different refractive indices. A higher light transmittance of the anti-reflective layer may be achieved with increased lamination of such materials.

In some embodiments, a second dielectric layer may be formed on the gate structures 145, 150, 155. A plurality of metal lines may be formed in the second dielectric layer. The metal lines may be electrically connected to the gate structures 145, 150, 155 through contacts and/or plugs.

Surface defects, such as dangling bonds, may be caused on the surface of the semiconductor substrate during the manufacturing process, for example, the grinding process, of the image sensor. The surface defects may thermally generate electric charges without any incident light. As a result, dark currents may be generated by the surface defects in the image sensor. The dark currents may be displayed on a display screen as a plurality of white spots. In a conventional image sensor, in order to passivate the surface defects, a protection layer and/or an impurity region are formed adjacent to surfaces of the semiconductor substrate. The conventional image sensor, however, has some limit to reduce the dark currents and the white spots.

The unit pixel 100 of the image sensor according to some embodiments of the present inventive concept may include the suppression gate 150 that is formed on the first surface 110a of the semiconductor substrate 110 and is configured to correspond to the photoelectric conversion region 115. As the negative voltage VN is applied to the suppression gate 150, the holes may be accumulated in the region adjacent to the first surface 110a of the semiconductor substrate 110, and the electric charges generated without any incident light may be coupled with the holes accumulated in the region adjacent to the first surface 110a of the semiconductor substrate 110. In addition, the suppression gate 150 is formed of polysilicon, and the suppression gate 150 and the transfer gate 145 are simultaneously formed. Thus, the dark currents of the image sensor including the unit pixel 100 may be effectively reduced without additional manufacturing processes.

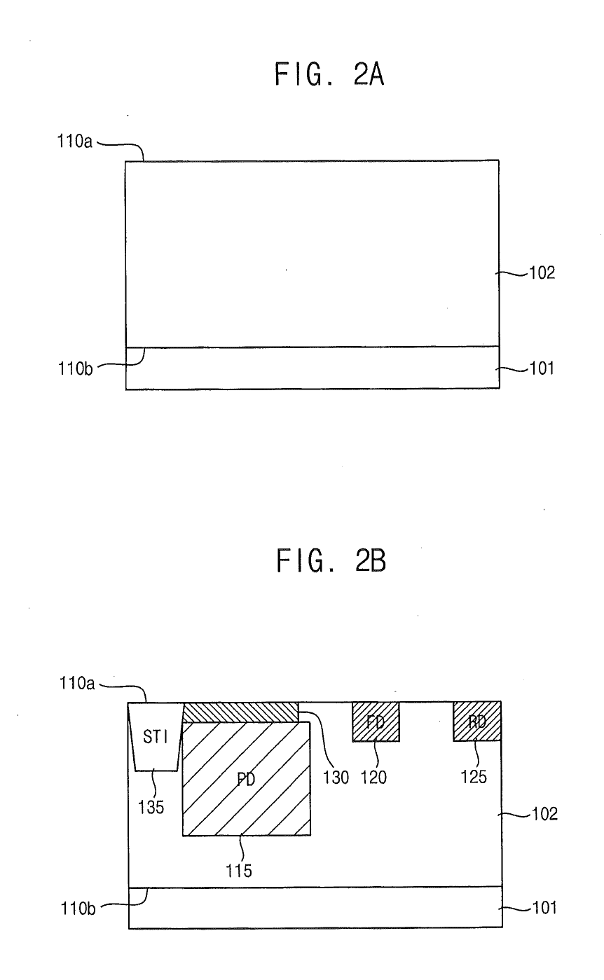

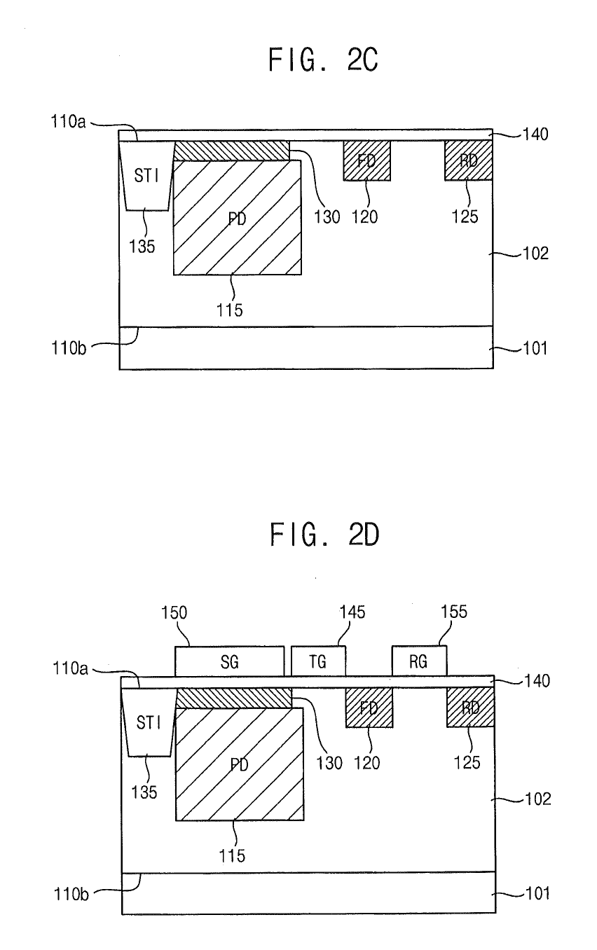

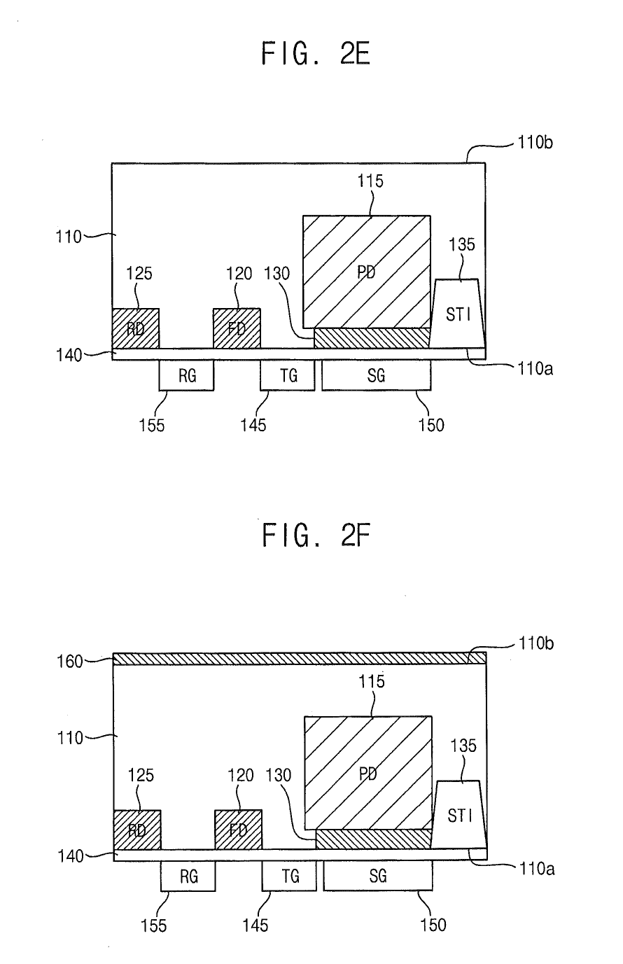

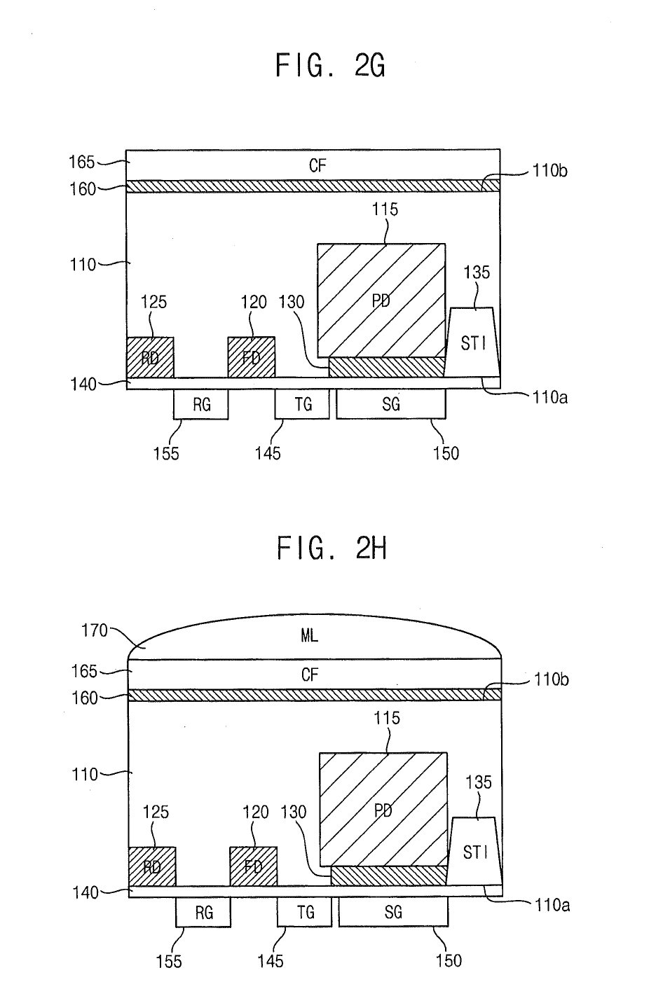

Referring now to FIGS. 2A-2H, cross-sections of a unit pixel illustrating processing steps in the fabrication of the unit pixel of FIG. 1 will be discussed. As illustrated in FIG. 2A, an epitaxial layer 102, for example, a p-type epitaxial layer, may be formed on a bulk silicon substrate 101, for example, a p-type bulk silicon substrate. The epitaxial layer 102 may be grown on the bulk silicon substrate 101 using silicon source gas, for example, silane, dichlorosilane (DCS), trichlorosilane (TCS), and/or hexachlorosilane (HCS), or a combination thereof. A semiconductor substrate 110 in FIG. 2A may have a front surface 110a and a back surface 110b by forming the epitaxial layer 102.

Referring now to FIG. 2B, a photoelectric conversion region 115, a floating diffusion region 120, a reset drain region 125, a first impurity region 130 and an isolation region 135 may be formed in the epitaxial layer 102. For example, photo diodes may be formed as the photoelectric conversion region 115 such that regions, for example, n-type regions, are formed in the epitaxial layer 102 using, for example, an ion implantation process. The first impurity region 130 may be formed such that regions, for example, p⁺ type regions, are formed in the epitaxial layer 102 above the photoelectric conversion region 115 using, for example, the ion implantation process. The floating diffusion region 125 and the reset drain region 125 may be formed such that regions, for example, n⁺ type regions, are formed in the epitaxial layer 102 using, for example, the ion implantation process. The isolation region 135 may be formed such that regions, for example, dielectric regions including field oxide, are vertically formed in the epitaxial layer 102 from the front surface 110a using, for example, a shallow trench isolation (STI) process and/or a local oxidation of silicon (LOCOS) process.

In some embodiments, the photoelectric conversion region 115 may be formed by laminating a plurality of doped regions. In these embodiments, an upper doped region may be an n+ type region that is formed by implanting n+ type ions in the p-type epitaxial layer 102, and a lower doped region may be an n− type region that is formed by implanting n-type ions in the p-type epitaxial layer 102.

As used herein, “p⁺” or “n⁺” refer to regions that are defined by higher carrier concentrations than are present in adjacent or other regions of the same or another layer or substrate. Similarly, “p⁻” or “n⁻” refer to regions that are defined by lower carrier concentrations than are present in adjacent or other regions of the same or another layer or substrate.

In some embodiments, the isolation region 135 may be formed by repeatedly implanting the dielectric material in the p-type epitaxial layer 102 with different energies. As the dielectric material is repeatedly implanted with different energies, the isolation region 135 may have an embossed shape. In some embodiments, the isolation region 135 may be formed before or after the photoelectric conversion region 115, the floating diffusion region 120, the reset drain region 125, and the first impurity region 130 are formed.

Furthermore, in some embodiments, a depth of the isolation region 135 may be greater than a depth of the photoelectric conversion region 115, which is referred herein to as a deep trench structure,

Referring now to FIG. 2C, a first dielectric layer 140 may be formed on the front surface 110a of the epitaxial layer 102, for example, the semiconductor substrate 110. The first dielectric layer 140 may be, for example, silicon oxide (SiOx), silicon oxynitride (SiOxNy), silicon nitride (SiNx), germanium oxynitride (GeOxNy), germanium silicon oxide (GeSixOy), and/or a material having a high dielectric constant, such as hafnium oxide (HfOx), zirconium oxide (ZrOx), aluminum oxide (AlOx), tantalum oxide (TaOx), hafnium silicate (HfSix), and/or zirconium silicate (ZrSix)).

Referring now to FIG. 2D, a transfer gate 145, a suppression gate 150 and a reset gate 155 may be formed on the first dielectric layer 140. For example, the transfer gate 145, the suppression gate 150 and the reset gate 155 may be formed by forming a gate conductive layer on the front surface 110a of the epitaxial layer 102, for example, on the first dielectric layer 140, and by patterning the gate conductive layer.

In the unit pixel of the image sensor according to some embodiments, the transfer gate 145, the suppression gate 150 and the reset gate 155 may be simultaneously formed, for example, using the same process. Thus, a thickness of the suppression gate 150 may be substantially the same as a thickness of the transfer gate 145. In addition, the gates 145, 150, 155 may be formed of polysilicon and may not be formed of metal and/or a metal compound. In other words, the gate conductive layer may be formed of only polysilicon, for example, gate poly (Gpoly).

In some embodiments, a second dielectric layer may be formed on the gates 145, 150, 155. The second dielectric layer may include multi-layer metal lines. The metal lines may be formed by forming a conductive layer of copper, tungsten, titanium and/or aluminum, and by patterning the conductive layer.

Referring now to FIG. 2E, the semiconductor substrate 110 may be formed by grinding the bulk silicon substrate 101 on which the epitaxial layer 102 is formed. The grinding process may be performed by, for example, a mechanical process and/or a chemical process. For example, the mechanical process may be performed by rubbing a polishing pad on the back surface 110b of the semiconductor substrate 110. In addition, the chemical process may be performed by injecting chemical materials, for example, “slurry”, between a polishing pad and the back surface 110b of the semiconductor substrate 110.

In some embodiments, the semiconductor substrate 110 may include only the epitaxial layer 102 after a complete removal of the bulk silicon substrate 101. In some embodiments, the semiconductor substrate 110 may be supported by, for example, the additional semiconductor substrate formed on the gates 145, 150, and 155. A wet etching process may be performed to reduce contamination on the back surface 110b of the semiconductor substrate 110.

Referring now to FIG. 2F, a protection layer 160 may be formed on the back surface 110b of the semiconductor substrate 110. For example, the protection layer 160 may be formed such that regions, for example, p+ type regions, are formed on the back surface 110b of the semiconductor substrate 110 using, for example, the ion implantation process. As discussed above with reference to FIG. 2E, when the grinding process is performed on the back surface 110b of the semiconductor substrate 110, surface defects, such as dangling bonds, may be caused on the back surface 110b of the semiconductor substrate 110 during the grinding process. To passivate the surface defects, the protection layer 160 may be doped with the p-type impurities with relatively high doping density.

Referring now to FIG. 2G, a color filter 165 may be formed on the protection layer 160. The color filter 165 may be disposed so as to correspond to the photoelectric conversion region 115. The color filter 165 may be formed using a dye process, a pigment dispersing process and/or a printing process. The color filter 165 may be formed by coating the back surface 110b of the semiconductor substrate 110, for example, the protection layer 160, with a photosensitive material, such as a photo-resist, and by patterning the photosensitivity material, for example, by performing a photolithography and lithography process using masks. In some embodiments, a planarization layer, for example, an over-coating layer (OCL), may be formed between the color filter 165 and a micro lens 170 in FIG. 2H.

Referring now to FIG. 2H, the micro lens 170 may be formed on the color filter 165. The micro lens 170 may be disposed so as to correspond to the photoelectric conversion region 115. For example, the micro lens 170 may be formed by forming patterns corresponding to the photoelectric conversion region 115 with photoresists having light-penetrability and by reflowing the patterns to have convex shapes. A bake process may be performed on the micro lens 170 to maintain the convex shapes.

FIGS. 3-6 are cross-sections of a unit pixel of an image sensor according to some embodiments of the present inventive concept. Referring first to FIG. 3, a unit pixel 100a of an image sensor includes a photoelectric conversion region 115a that is formed in a semiconductor substrate 110, and a transfer gate 145 and a suppression gate 150 that are formed on the semiconductor substrate 110. The unit pixel 100a of the image sensor may further include a floating diffusion region 120, a reset drain region 125, an isolation region 135, a first dielectric layer 140, a reset gate 155, a protection layer 160, a color filter 165 and a micro lens 170.

In comparison with the unit pixel 100 of FIG. 1, the first impurity region 130 in FIG. 1 may be omitted in the unit pixel 100a because a function of the suppression gate 150 may be substantially the same as a function of the first impurity region 130. For example, the process of forming p+ type regions above the photoelectric conversion region 115a, which is discussed above with reference to FIG. 2B, may be omitted. In these embodiments, when the n-type regions for the photoelectric conversion region 115a are formed in the semiconductor substrate 110, an amount of injection of n-type impurities may be reduced. Accordingly, in the unit pixel 100a of FIG. 3, the photoelectric conversion region 115a may have relatively small electric field, and thus noises may be reduced in the unit pixel 100a although a size of the unit pixel 100a decreases.

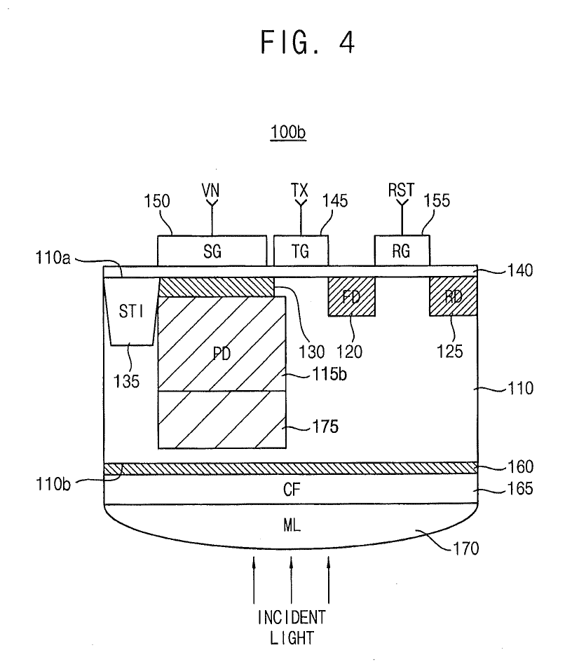

Referring now to FIG. 4, a unit pixel 100b of an image sensor includes a photoelectric conversion region 115b that is formed in a semiconductor substrate 110, and a transfer gate 145 and a suppression gate 150 that are formed on the semiconductor substrate 110. The unit pixel 100b of the image sensor may further include a floating diffusion region 120, a reset drain region 125, a first impurity region 130, an isolation region 135, a first dielectric layer 140, a reset gate 155, a protection layer 160, a color filter 165, a micro lens 170 and a second impurity region 175.

In comparison with the unit pixel 100 of FIG. 1, the unit pixel 100b may further include the second impurity region 175. The second impurity region 175 may be formed in the semiconductor substrate 110 under the photoelectric conversion region 115b. The second impurity region 175 may be doped with the first-type impurities of the opposite conductivity type to that of the semiconductor substrate 110, for example, the same conductivity type to that of the photoelectric conversion region 115b and may be doped with lower doping density than the photoelectric conversion region 115b. For example, the second impurity region 175 may be formed such that regions, for example, n− type regions, are formed in the semiconductor substrate 110 under the photoelectric conversion region 115b using, for example, the ion implantation process.

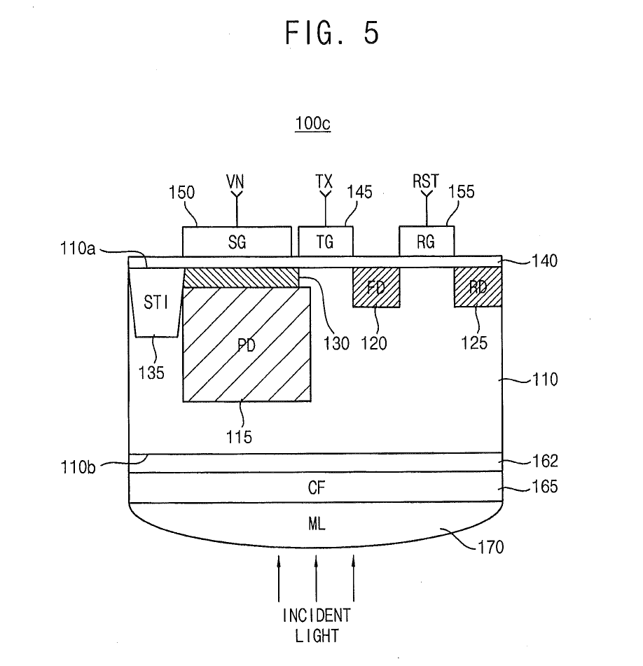

Referring now to FIG. 5, a unit pixel 100c of an image sensor includes a photoelectric conversion region 115 that is formed in a semiconductor substrate 110, and a transfer gate 145 and a suppression gate 150 that are formed on the semiconductor substrate 110. The unit pixel 100b of the image sensor may further include a floating diffusion region 120, a reset drain region 125, a first impurity region 130, an isolation region 135, a first dielectric layer 140, a reset gate 155, a second dielectric layer 162, a color filter 165 and a micro lens 170.

In comparison with the unit pixel 100 of FIG. 1, the protection layer 160 in FIG. 1 may be changed into the second dielectric layer 162 in the unit pixel 100c. In other words, the second dielectric layer 162 in the unit pixel 100c may be formed between the second surface 110b of the semiconductor substrate 110 and the color filter 165.

In some embodiments, the second dielectric layer 162 may include negative fixed charges, and thus the image sensor including the unit pixel 100c may effectively reduce the dark currents. For example, the second dielectric layer 162 may be formed of metal oxide including a metal element, for example, zirconium (Zr), aluminum (Al), tantalum (Ta), titanium (Ti), Yttrium (Y) and/or lanthanoids. The second dielectric layer 162 may have at least one crystallized region.

In the BIS, noise may occur due to surface defects that exist, for example, surface defects caused by a manufacturing process, in a region adjacent to the back surface 110b of the semiconductor substrate 110. If the second dielectric layer 162 includes the negative fixed charges, the holes may be accumulated in a region adjacent to the back surface 110b of the semiconductor substrate 110. The electric charges generated by surface defects without any incident light may be coupled with the holes accumulated in the region adjacent to the back surface 110b of the semiconductor substrate 110. Thus, the dark currents of the image sensor including the unit pixel 100c may be reduced without the protection layer 160, and light guiding efficiency and light sensitivity may be improved in the image sensor according to some embodiments.

In some embodiments, the second dielectric layer 162 may include an optical shielding layer for reducing or, possibly preventing, incident light from entering an optical black area.

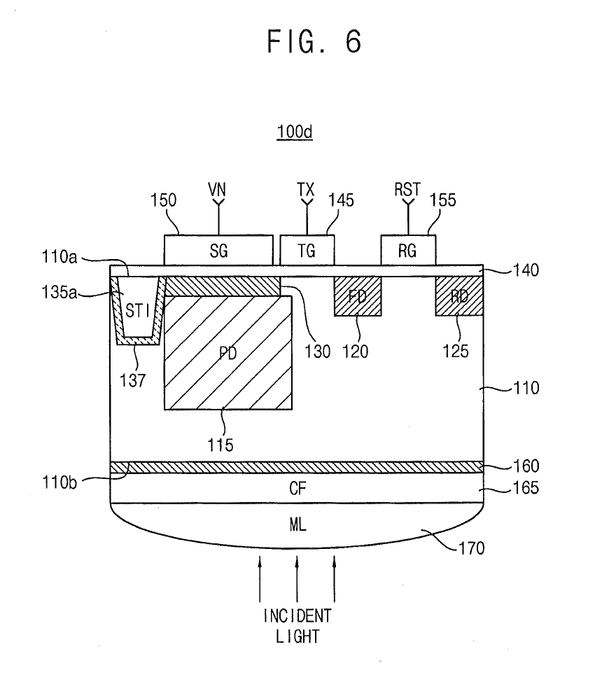

Referring now to FIG. 6, a unit pixel 100d of an image sensor includes a photoelectric conversion region 115 that is formed in a semiconductor substrate 110, and a transfer gate 145 and a suppression gate 150 that are formed on the semiconductor substrate 110. The unit pixel 100b of the image sensor may further include a floating diffusion region 120, a reset drain region 125, a first impurity region 130, an isolation region 135a, a surface doping layer 137, a first dielectric layer 140, a reset gate 155, a protection layer 160, a color filter 165 and a micro lens 170.

In comparison with the unit pixel 100 of FIG. 1, the unit pixel 100d may further include the surface doping layer 137 formed to surround the isolation region 135a. The surface doping layer 137 may be doped with the second-type impurities of the same conductivity type to that of the semiconductor substrate 110, and may be doped with higher doping density than the semiconductor substrate 110. For example, after the isolation region 135a is formed by filling a portion of the semiconductor substrate 110 with dielectric material, the surface doping layer 137 may be formed such that regions, for example, p+ type regions) are formed in the semiconductor substrate 110 to surround the isolation region 135a using, for example, the ion implantation process such as a PLAsma Doping (PLAD).

In the manufacturing process of the image sensor including the unit pixel 100d, surface defects may be caused in a region of the semiconductor substrate 110 adjacent to the isolation region 135a. In embodiments illustrated in FIG. 6, the electric charges generated by the surface defects without any incident light may be coupled with the holes in the surface doping layer 137. Thus, the dark currents in the image sensor including the unit pixel 100d may be reduced, and the surface defects may be passivated.

In some embodiments, the isolation region 135 in FIG. 1 may be filled with dielectric material including negative fixed charges to passivate the surface defects, instead of further forming the surface doping layer 137 as illustrated in FIG. 6. If the isolation region 135 includes the negative fixed charges, the holes may be accumulated in a region adjacent to the isolation region 135 in the semiconductor substrate 110. Electric charges generated by surface defects without any incident light may be coupled with the holes accumulated in the region adjacent to isolation region 135 in the semiconductor substrate 110. Thus, the dark currents in the image sensor including the unit pixel may be reduced, and the surface defects may be passivated.

Various examples of the unit pixel of the image sensor are discussed with respect to FIGS. 1 and 3-6. The unit pixel of the image sensor according to some embodiments may be implemented with a combination of at least two of the various examples, for example, an example of omitting the first impurity region (FIG. 3), an example of further including the second impurity region (FIG. 4), an example of changing the protection layer into the second dielectric layer (FIG. 5), and an example of further including the surface doping layer (FIG. 6).

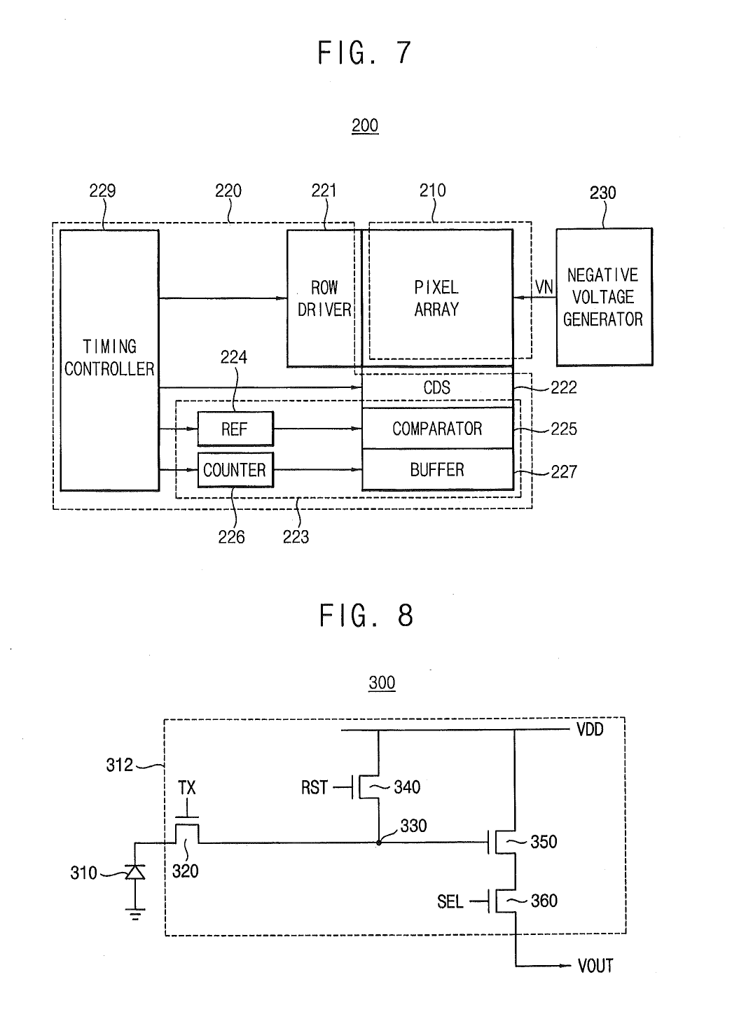

Referring now to FIG. 7, a block diagram illustrating an image sensor including the unit pixel according to some embodiments of the present inventive concept will be discussed. As illustrated in FIG. 7, an image sensor 200 includes a pixel array 210 and a signal processing unit 220. The image sensor 200 may further include a negative voltage generator 230.

The pixel array 210 generates electric signals based on incident lights. The pixel array 210 may include a plurality of unit pixels that are arranged in a matrix form. Each unit pixel may be one of the unit pixel 100 of FIG. 1, the unit pixel 100a of FIG. 3, the unit pixel 100b of FIG. 4, the unit pixel 100c of FIG. 5 and the unit pixel 100d of FIG. 6. Each unit pixel includes the suppression gate that is formed on the first surface of the semiconductor substrate and is configured to correspond to the photoelectric conversion region. A negative voltage VN is applied to the suppression gate. Furthermore, the suppression gate is formed of polysilicon, and the suppression gate and the transfer gate are simultaneously formed. Accordingly, the dark currents of the image sensor including the unit pixels may be effectively reduced without additional manufacturing processes.

The signal processing unit 220 generates image data based on the electric signals. The signal processing unit 220 may include a row driver 221, a correlated double sampling (CDS) unit 222, an analog-to-digital converting (ADC) unit 223 and a timing controller 229.

The row driver 221 is connected with each row of the pixel array 210. The row driver 221 may generate driving signals to drive each row. For example, the row driver 221 may drive the plurality of unit pixels included in the pixel array 210 row by row.

The CDS unit 222 performs a CDS operation, for example, analog double sampling (ADS), by obtaining a difference between reset components and measured signal components using capacitors and switches, and outputs analog signals corresponding to effective signal components. The CDS unit 222 may include a plurality of CDS circuits that are connected to column lines, respectively. The CDS unit 222 may output the analog signals corresponding to the effective signal components column by column.

The ADC unit 223 converts the analog signals corresponding to the effective signal components into digital signals. The ADC unit 223 may include a reference signal generator 224, a comparison unit 225, a counter 226 and a buffer unit 227. The reference signal generator 224 may generate a reference signal, for example, a ramp signal having a slope, and provide the reference signal to the comparison unit 225. The comparison unit 225 may compare the reference signal with the analog signals corresponding to the effective signal components, and output comparison signals having respective transition timings according to respective effective signal component column by column. The counter 226 may perform a counting operation to generate a counting signal, and provide the counting signal to the buffer unit 227. The buffer unit 227 may include a plurality of latch circuits respectively connected to the column lines. The buffer unit 227 may latch the counting signal of each column line in response to the transition of each comparison signal, and output the latched counting signal as the image data.

The timing controller 229 controls operation timings of the row driver 221, the CDS unit 222, and the ADC unit 223. The timing controller 229 may provide timing signals and control signals to the row driver 221, the CDS unit 222, and the ADC unit 223.

In some embodiments, the image sensor 200 may perform a digital double sampling (DDS) as the CDS. For DDS, the reset signal and the measured image signal may be both converted to respective digital signals. The final image signal may be determined from a difference of such respective digital signals.

The negative voltage generator 230 may generate the negative voltage VN applied to the suppression gate. The negative voltage generator 230 may include a charge pump or a DC-DC converter. Although various voltages are generated by dividing a positive power supply voltage and are provided to the image sensor 200, the negative voltage VN cannot be generated by a typical voltage dividing scheme. The negative voltage generator 230 may generate the negative voltage VN based on the positive power supply voltage, using the charge pump or the DC-DC converter.

In some embodiments, the timing controller 229 may control a supply of the negative voltage VN. For example, the negative voltage VN may be always applied to the suppression gate by the timing controller 229 when the image sensor 200 is enabled. For another example, the negative voltage VN may be always applied to the suppression gate by the timing controller 229 during a predetermined time period, e.g., an integration mode or a readout mode.

In some embodiments, the negative voltage VN may be provided from an external device, such as an external negative voltage generator without departing from the scope of the present inventive concept.

Referring now to FIG. 8, a circuit diagram illustrating an example of a unit pixel included in the image sensor of FIG. 7 in accordance with some embodiments of the present inventive concept will be discussed. As illustrated in FIG. 8, the unit pixel 300 may include a photoelectric conversion unit 310 and a signal generation unit 312.

The photoelectric conversion unit 310 performs a photoelectric conversion operation. For example, the photoelectric conversion unit 310 may convert the incident lights into the photo-charges during a first operation mode, for example, the integration mode. If an image sensor including the unit pixel 300 is a CMOS image sensor, image information on an object to be captured is obtained by collecting charge carriers, for example, electron-hole pairs, in the photoelectric conversion unit 310 proportional to intensity of incident lights through an open shutter of the CMOS image sensor, during the integration mode.

The signal generation unit 312 generates an electric signal based on the photo-charges generated by the photoelectric conversion operation during a second operation mode, for example, the readout mode. If the image sensor including the unit pixel 300 is a CMOS image sensor, the shutter is closed, the image information in a form of charge carriers is converted into the electric signals, and the image data is generated based on the electric signals, during the readout mode after the integration mode.

The unit pixel 300 may have various structures including, for example, one-transistor structure, three-transistor structure, four-transistor structure, five-transistor structure, structure where some transistors are shared by a plurality of unit pixels, and the like. As illustrated in FIG. 8, the unit pixel 300 may have four-transistor structure. In some embodiments, the signal generation unit 312 may include a transfer transistor 320, a reset transistor 340, a drive transistor 350, a select transistor 360 and a floating diffusion node 330. The floating diffusion node 330 may correspond to the floating diffusion region and may be connected to a capacitor.

The transfer transistor 320 may include a first electrode connected to the photoelectric conversion unit 310, a second electrode connected to the floating diffusion node 330, and a gate electrode applied to a transfer signal TX. The reset transistor 340 may include a first electrode applied to a power supply voltage VDD, a second electrode connected to the floating diffusion node 330, and a gate electrode applied to a reset signal RST. The drive transistor 350 may include a first electrode applied to the power supply voltage VDD, a gate electrode connected to the floating diffusion node 230, and a second electrode. The select transistor 360 may include a first electrode connected to the second electrode of the drive transistor 350, a gate electrode applied to a select signal SEL, and a second electrode providing an output voltage VOUT.

Operations of the image sensor 200 in accordance with some embodiments of the present inventive concept will now be discussed with respect to FIGS. 7 and 8. When the reset transistor 340 is turned on by raising a voltage level of a gate RST of the reset transistor 340, a voltage level of the floating diffusion node 330, which is a sensing node, increases up to the power supply voltage VDD.

When an external light is incident onto the photoelectric conversion unit 310 during the integration mode, electron-hole pairs are generated in proportion to the amount of the incident light.

When a voltage level of a gate TX of the transfer transistor 320 increases during the readout mode after the integration mode, electrons integrated within the photoelectric conversion unit 310 are transferred to the floating diffusion node 330 through the transfer transistor 320. The electric potential of the floating diffusion node 330 drops in proportion to the amount of the transferred electrons, and then the electric potential of the source in the drive transistor 350 is varied depending on the amount of the transferred electrons of the floating diffusion node 330.

When the select transistor 360 is turned on by raising a voltage level of a gate SEL of the selection transistor 360, the electric potential of the floating diffusion node 330 is transferred, as an output signal, through the drive transistor 350. The unit pixel 300 outputs the electric signal VOUT corresponding to the image information on an object to be captured, and the signal processing unit 220 generates image data based on the electric signals VOUT.

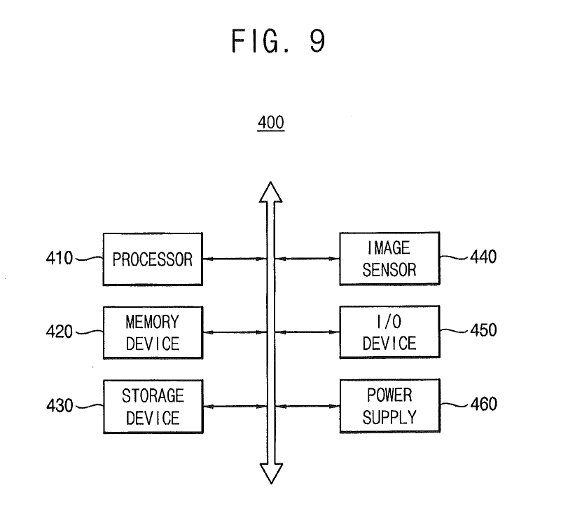

Referring now to FIG. 9, a diagram illustrating a computing system according to some embodiments of the present inventive concept will be discussed. As illustrated in FIG. 9, a computing system 400 includes a processor 410, a memory device 420, a storage device 430, an input/output (I/O) device 450, a power supply 460 and an image sensor 440. In some embodiments, computing system 400 may further include a plurality of ports for communicating a video card, a sound card, a memory card, a universal serial bus (USB) device and/or other electric devices.

The processor 410 may perform various computing functions. The processor 410 may be a micro processor and/or a central processing unit (CPU). The processor 410 may be connected to the memory device 420, the storage device 430, and the I/O device 450 via a bus, for example, an address bus, a control bus, and/or a data bus. The processor 410 may be connected to an extended bus, for example, a peripheral component interconnection (PCI) bus.

The memory device 420 may store data for operations of the computing system 400. For example, the memory device 420 may include a dynamic random access memory (DRAM) device, a static random access memory (SRAM) device, an erasable programmable read-only memory (EPROM) device, an electrically erasable programming read-only memory (EEPROM) device and/or a flash memory device.

The storage device 430 may include a solid state drive device, a hard disk drive device and/or a CD-ROM device. The I/O device 450 may include input devices, for example, a keyboard, a keypad and/or a mouse, and output devices, for example, a printer and/or a display device. The power supply 460 may provide a power for operations of the computing system 400.

The image sensor 440 may communicate with the processor 410 via the bus or other communication links. The image sensor 440 may include at least one of the unit pixel 100 of FIG. 1, the unit pixel 100a of FIG. 3, the unit pixel 100b of FIG. 4, the unit pixel 100c of FIG. 5 and the unit pixel 100d of FIG. 6. Each unit pixel includes the suppression gate that is formed on the first surface of the semiconductor substrate and is configured to correspond to the photoelectric conversion region. A negative voltage VN is applied to the suppression gate. In addition, the suppression gate is formed of polysilicon, and the suppression gate and the transfer gate are simultaneously formed. Accordingly, the dark currents of the image sensor including the unit pixels may be effectively reduced without additional manufacturing processes.

According to some embodiments, the computing system 400 and/or components of the computing system 400 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

In some embodiments, the image sensor 440 and the processor 410 may be fabricated as one integrated circuit chip. In some embodiments, the image sensor 440 and the processor 410 may be fabricated as two separate integrated circuit chips.

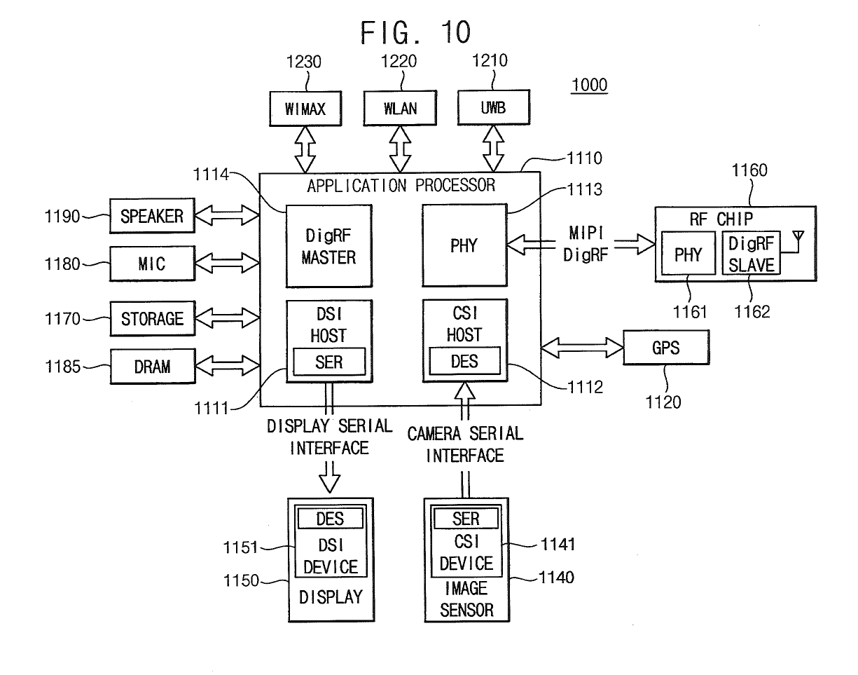

Referring now to FIG. 10, a block diagram illustrating an example of an interface used for the computing system of FIG. 9 will be discussed. As illustrated in FIG. 10, the computing system 1000 may be implemented by a data processing device that uses, or supports a mobile industry processor interface (MIPI) interface, for example, a mobile phone, a personal digital assistant (PDA), a portable multimedia player (PMP), and/or a smart phone. The computing system 1000 may include an application processor 1110, an image sensor 1140 and/or a display device 1150.

A CSI host 1112 of the application processor 1110 may perform a serial communication with a CSI device 1141 of the image sensor 1140 using a camera serial interface (CSI). In some embodiments, the CSI host 1112 may include a light deserializer (DES), and the CSI device 1141 may include a light serializer (SER). A DSI host 1111 of the application processor 1110 may perform a serial communication with a DSI device 1151 of the display device 1150 using a display serial interface (DSI). In some embodiments, the DSI host 1111 may include a light serializer (SER), and the DSI device 1151 may include a light deserializer (DES).

The computing system 1000 may further include a radio frequency (RF) chip 1160. The RF chip 1160 may perform a communication with the application processor 1110. A physical layer (PHY) 1113 of the computing system 1000 and a physical layer (PHY) 1161 of the RF chip 1160 may perform data communications based on a MIPI DigRF. The application processor 1110 may further include a DigRF MASTER 1114 that controls the data communications of the PHY 1161.

The computing system 1000 may include a global positioning system (GPS) 1120, a storage 1170, a MIC 1180, a DRAM device 1185, and a speaker 1190. In addition, the computing system 1000 may perform communications using an ultra wideband (UWB) 1220, a wireless local area network (WLAN) 1220 and/or a worldwide interoperability for microwave access (WIMAX) 1230. However, it will be understood that embodiments of the present inventive concept are not limited to this configuration.

Thus, as briefly discussed above, the unit pixel of the image sensor according to some embodiments include a suppression gate that on the first surface of the semiconductor substrate and configured to correspond to the photoelectric conversion region. As the negative voltage is applied to the suppression gate, the holes may be accumulated in the region adjacent to the first surface of the semiconductor substrate, and the electric charges generated without any incident light may be coupled with the holes accumulated in the region adjacent to the first surface of the semiconductor substrate. In addition, the suppression gate is formed of polysilicon, and the suppression gate and the transfer gate are simultaneously formed. Thus, the dark currents of the image sensor including the unit pixel may be effectively reduced without additional manufacturing processes.

Although the unit pixel and the image sensor according to some embodiments are mainly described based on the BIS, the inventive concept may be employed in a frontside illuminated image sensor. Furthermore, although the unit pixel and the image sensor according to some embodiments are mainly described based on the CMOS image sensor, the inventive concept may be employed in various image sensors, such as the CCD image sensor.

The above described embodiments may be applied to an image sensor, and an electronic system having the image sensor. For example, the electronic system may be a system using an image sensor, for example, a computer, a digital camera, a 3-D camera, a cellular phone, a personal digital assistant (PDA), a scanner, a navigation system, a video phone, a surveillance system, an auto-focusing system, a tracking system, a motion-sensing system and/or an image-stabilization system.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A unit pixel included in an image sensor, the unit pixel comprising:
a photoelectric conversion region in a semiconductor substrate, the photoelectric conversion region configured to generate photo-charges corresponding to incident light;
a transfer gate on a first surface of the semiconductor substrate, the transfer gate configured to transmit the photo-charges from the photoelectric conversion region to a floating diffusion region in the semiconductor substrate; and
a suppression gate on the first surface of the semiconductor substrate, the suppression gate configured to correspond to the photoelectric conversion region, the suppression gate including polysilicon and a negative voltage applied to the suppression gate to reduce dark currents is generated adjacent to the first surface of the semiconductor substrate.

2. The unit pixel of claim 1, wherein the semiconductor substrate has a first conductivity type and wherein the photoelectric conversion region is doped impurities having a second conductivity type, opposite first conductivity type.

3. The unit pixel of claim 2, further comprising a first impurity region in the semiconductor substrate above the photoelectric conversion region, the first impurity region being doped impurities having the first conductivity type and having a higher doping concentration than the semiconductor substrate.

4. The unit pixel of claim 2, further comprising:
a first impurity region in the semiconductor substrate under the photoelectric conversion region, the first impurity region being doped impurities having the second conductivity type and having a lower doping concentration than the photoelectric conversion region.

5. The unit pixel of claim 1, wherein a thickness of the suppression gate is substantially the same as a thickness of the transfer gate.

6. The unit pixel of claim 1, further comprising:
a color filter on a second surface of the semiconductor substrate, the color filter configured to correspond to the photoelectric conversion region; and
a micro lens on the color filter, the micro lens configured to correspond to the photoelectric conversion region.

7. The unit pixel of claim 6, wherein the incident light passes through the micro lens, the color filter and the second surface of the semiconductor substrate, and reaches the photoelectric conversion region.

8. The unit pixel of claim 6, further comprising:
a protection layer between the second surface of the semiconductor substrate and the color filter, the protection layer being doped impurities having the second conductivity type and having a higher doping concentration than the semiconductor substrate.

9. The unit pixel of claim 6, further comprising a dielectric layer between the second surface of the semiconductor substrate and the color filter.

10. The unit pixel of claim 9, wherein the dielectric layer includes negative fixed charges.

11. The unit pixel of claim 6, wherein the color filter includes one of a red filter, a green filter and a blue filter.

12. The unit pixel of claim 6, wherein the color filter includes one of a yellow filter, a magenta filter and a cyan filter.

13. The unit pixel of claim 1, further comprising an isolation region surrounding the unit pixel.

14. An image sensor, comprising:
a pixel array including a plurality of unit pixels, the pixel array configured to generate electric signals based on incident light; and
a signal processing unit configured to generate image data based on the electric signals, and
wherein each unit pixel comprises:
a photoelectric conversion region in a semiconductor substrate, the photoelectric conversion region configured to generate photo-charges corresponding to the incident light;
a transfer gate on a first surface of the semiconductor substrate, the transfer gate configured to transmit the photo-charges from the photoelectric conversion region to a floating diffusion region in the semiconductor substrate; and
a suppression gate on the first surface of the semiconductor substrate, the suppression gate configured to correspond to the photoelectric conversion region and including polysilicon and a negative voltage applied to the suppression gate to reduce dark currents is generated adjacent to the first surface of the semiconductor substrate.

15. The image sensor of claim 14, further comprising a negative voltage generator configured to generate the negative voltage applied to the suppression gate.
